(19) United States
(12) Patent Application Publication
(10) Pub. No.: US 2012/0222617 A1
(43) Pub. Date: Sep. 6, 2012

(54) PLASMA SYSTEM AND METHOD OF PRODUCING A FUNCTIONAL COATING

(76) Inventors: Stefan GROSSE, Gerlingen (DE); Sascha Henke, Weil der Stadt (DE); Susanne Spindler, Stuttgart (DE)

(21) Appl. No.: 13/472,830

(22) Filed: May 16, 2012

Related U.S. Application Data
(62) Division of application No. 10/240,474, filed on Apr. 26, 2010.

(30) Foreign Application Priority Data
Feb. 2, 2001 (DE) 101 04 613.8-33

(51) Int. Cl. C23C 16/513

(52) U.S. Cl. 118/723 I

(57) ABSTRACT

A plasma system has at least one inductively coupled high-frequency plasma jet source having a burner body delimiting a plasma generating space, having an outlet orifice for the plasma jet, and a chamber communicating with the plasma jet source through the outlet orifice, having a substrate situated in the chamber, where it is exposed to the plasma jet. The substrate is situated on a substrate electrode to which an electric voltage may be applied. In addition, a method of producing a functional coating on the substrate using such a plasma system is also described. In a preferred embodiment, during operation of the plasma system, both the plasma jet and the electric voltage on the substrate electrode are pulsed and/or a pressure gradient is maintained between the interior of the plasma jet source and the interior of the chamber.

### CROSS-REFERENCE TO RELATED APPLICATION

This application is a divisional application of U.S. patent application Ser. No. 10/240,474, filed Apr. 26, 2010, which was a national-phase application based on international application PCT/DE01/04565 filed on Dec. 5, 2001 and claimed the benefit of and priority of German Patent Application No. 101 04 613.8, which was filed in Germany on Feb. 2, 2001, the entire contents of all of which are expressly incorporated herein by reference.

### FIELD OF THE INVENTION

The present invention relates to a plasma system having a high-frequency inductively coupled plasma jet source and to a method of producing a functional coating on a substrate.

BACKGROUND INFORMATION Applying functional coatings to substrates is a widely used method of imparting desired properties to the surfaces of workpieces and/or components. A conventional method of producing such functional layers is by plasma coating in a medium-high or high vacuum, which requires complex evacuation techniques and yields relatively low coating rates. Therefore, this method is time-intensive and expensive.

Thermal plasmas in particular which allow higher coating rates in the range of mm/h to able achieved are suitable for coating substrates in the atmospheric and subatmospheric pressure range. In this regard, reference is made to R. Henne, Contribution to Plasma Physics, 39 (1999) pages 385-397, for example. Of the thermal plasma sources, the high-frequency inductively coupled plasma jet source (HF-ICP jet source) is especially promising, such as that described by E. Pfender and C. H. Chang “Plasma Spray Jets and Plasma Particulate Interaction: Modeling and Experiments,” Convention Volume of the 6^{th} Workshop on Plasma Technology, Technical University of Illmenau, 1998. Furthermore, German Published Patent Application No. 199 58 474 has proposed a method of producing functional layers by using such a plasma jet source.

The advantages of the HF-ICP jet source include the range of operating pressures in the source, usually extending from 50 mbar to 1 bar or more, and also the great variety of materials that may be used and deposited with such a plasma jet source. In particular, due to the fact that the starting materials are introduced axially into the very hot plasma jet, hard substances having a very high melting point may also be used. Another advantage of the HF-ICP jet source is that it works without electrodes, i.e., contamination of the layers produced by the jet source electrode material are prevented.

One disadvantage of the known HF-ICP jet sources and plasma systems using such plasma jet sources is the high temperatures in the plasma jet of several thousand degrees Celsius to which the substrate that is to be coated is also exposed. The choice of usable substrates is considerably restricted in this regard. Another disadvantage is that to produce layer systems on the substrate, such as those currently produced by CVD methods, for example, a minimum energy of particles impinging on the substrate is often necessary. This is true in particular in deposition of DLC (diamond-like carbon) coatings. This minimum energy of the impinging ions is not achieved with the high-frequency inductively coupled plasma jet sources known in the past and the plasma systems equipped with them.

### BRIEF SUMMARY OF THE INVENTION

An object of the present invention is to provide a plasma system having an inductively coupled HF plasma jet source and a method of producing functional coatings, the deposition of which requires a higher energy of the ions from the plasma striking the substrate than provided by conventional HF-ICP plasma jet sources. In particular, the object of the present invention is to provide a plasma system and a method with which it is possible to produce hard carbon coatings, i.e., DLC layers, in a low vacuum.

The plasma system according to the present invention having a high-frequency inductively coupled plasma jet source and the method according to the present invention for producing a functional coating on a substrate have the advantage over the related art that they permit the production of layers and/or layer systems which could previously be produced only by CVD methods.

Because the pressure prevailing in the chamber in deposition of layers with HF-ICP plasma jet sources is reduced from 100 mbar to 1 bar, as is customary, to less than 50 mbar, this advantageously yields the result that a sufficient mean free path length is available to the ions present in the plasma, and thus the electric voltage supplied to the substrate electrode and thereby to the substrate connected to the substrate electrode also manifests an adequate effect with regard to the desired acceleration. In addition, this pressure significantly lowers the thermal load on the substrate being coated.

On the other hand, it is advantageous that the plasma system according to the present invention requires only a low vacuum of less than 50 mbar, even in the chamber in which the substrate is located, to ensure adequate ion energies for the desired coating processes and/or surface modifications. It is possible to reliably and quickly produce a low vacuum in the chamber of the plasma system by using conventional pumping devices, and this requires much less equipment and is less time consuming in comparison with a medium-high or high vacuum, as required for CVD methods. Due to the relatively high pressure in the chamber of the plasma system, it is also possible to process workpieces made of sintered materials which release a large amount of gas.

It is also advantageous that due to the applied substrate electrode voltage and the selected pressure in the plasma system the reactive properties of the HF-ICP plasma are improved for producing a coating and/or achieving a surface modification on the substrate.

Thus, on the whole, the method according to the present invention is a high-rate deposition method which is implementable in a low vacuum in short process times, i.e., pumping times, and which is suitable for deposition, i.e., production, of coatings on all substrates that are of industrial relevance, e.g., high-grade steel, other electrically conducting materials, ceramics, etc.

Thus, due to the fact that the high-frequency plasma jet source and the chamber containing the substrate communicate only through the outlet orifice of the plasma jet source, it is readily possible to maintain a pressure difference between the interior of the plasma jet source and the interior of the chamber.

It is furthermore advantageous if the action of the electric voltage on the substrate electrode is correlated with a periodic variation in intensity of the plasma jet produced by the plasma jet source. The thermal load on the substrate is further reduced in this way, and also physical disequilibrium states occur in the plasma to a great extent due to the fluctuation in intensity of the plasma jet, which is preferably also extinguished periodically, and these disequilibrium states may be used to deposit novel coatings on the substrate. With regard to the choice of materials supplied to the plasma jet source, i.e., the plasma jet produced, for producing the functional coating on the substrate, there are also a great variety of options, including those proposed in German Published Patent Application No. 199 58 474.

Other advantageous refinements of the present invention involve providing a cooling device for cooling the substrate and/or a movable mount, preferably a mount that is movable in all directions or rotatable in space, so that the substrate is easily oriented relative to the plasma jets and may also be cooled during plasma deposition if desired.

It is particularly advantageous if the electric voltage supplied to the substrate electrode is an electric voltage which is variable over time, in particular a pulsed electric voltage, which may also be provided with an adjustable positive or negative offset voltage and/or pulsed with a virtually freely selectable pulse-pause ratio. Another parameter that is easily varied and adapted to the requirements of the individual case is also the shape of the envelope of the electric voltage that is variable over time and may have, for example, a saw-tooth, triangular or sinusoidal curve. The electric voltage used may also be a direct voltage.

Other parameters that are easily varied with regard to the concrete signal shape of the electric voltage used include its edge steepness, its amplitude, and its frequency. In addition, it should be emphasized that the variation over time in the voltage injected into the substrate electrode need not necessarily be periodic.

### BRIEF DESCRIPTION OF THE DRAWINGS

FIG. 1 shows a first embodiment of a plasma system having an ICP plasma jet source in a sectional view.

FIG. 2 shows an example of a variation in intensity of the plasma jet over time.

FIG. 3a shows a first photograph of the plasma jet emerging from the plasma jet source as a function of time, the jet being pulsed according to FIG. 2.

FIG. 3b shows a second photograph of the plasma jet emerging from the plasma jet source as a function of time, the jet being pulsed according to FIG. 2.

FIG. 3c shows a third photograph of the plasma jet emerging from the plasma jet source as a function of time, the jet being pulsed according to FIG. 2.

FIG. 3d shows a fourth photograph of the plasma jet emerging from the plasma jet source as a function of time, the jet being pulsed according to FIG. 2.

FIG. 3e shows a fifth photograph of the plasma jet emerging from the plasma jet source as a function of time, the jet being pulsed according to FIG. 2.

FIG. 3f shows a sixth photograph of the plasma jet emerging from the plasma jet source as a function of time, the jet being pulsed according to FIG. 2.

FIG. 3g shows a seventh photograph of the plasma jet emerging from the plasma jet source as a function of time, the jet being pulsed according to FIG. 2.

FIG. 3h shows an eighth photograph of the plasma jet emerging from the plasma jet source as a function of time, the jet being pulsed according to FIG. 2.

FIG. 4 shows a photograph of a plasma jet emerging from a plasma jet source at a high velocity.

FIG. 5 shows a detail of the plasma jet source according to FIG. 1.

### DETAILED DESCRIPTION

The present invention is based on a high-frequency, inductively coupled plasma jet source such as that known in a similar form from E. Pfender and C. H. Chang, “Plasma Spray Jets and Plasma Particulate Interaction: Modeling and Experiments,” Convention Volume of the 6^{th} Workshop on Plasma Technology, Technical University of Illmenau. In addition, a coating method similar to that already described in German Published Patent Application No. 199 58 474 is implemented with this system.

Specifically, FIG. 1 shows in detail a high-frequency, inductively coupled plasma jet source 5 having a pot-shaped burner body 25, which has on one side an outlet orifice 26, e.g., circular in design and having a diameter of 1 cm to 10 cm, provided with an orifice constrictor 22, which is preferably variably adjustable, i.e., shaped. In addition, plasma jet source 5 has a coil 17 integrated into burner body 25 in the area of outlet orifice 26, e.g., a water-cooled copper coil which may also be coiled around burner body 25 as an alternative.

In addition, an inlet 10 in the form of a conventional injector for supplying an injector gas 11, a first cylindrical sleeve 14, and a second cylindrical sleeve 15 are provided on the side of burner body 25 facing away from outlet orifice 26. First sleeve 14 and/or second sleeve 15 are each designed to be concentric with the side wall of burner body 25, second sleeve 15 being used primarily to keep a plasma 21 produced in a plasma generating space 27 in burner body 25 away from the walls of burner body 25.

To do so, an enveloping gas 13 is introduced into burner body 25 through a suitable gas inlet between first sleeve 14 and second sleeve 15, this burner body also having the function of blowing plasma 21 thus produced out of plasma jet source 5 through outlet orifice 26 in such a way as to form a plasma jet 20 which is largely bundled when it impinges on substrate 19 in a chamber 40 on a substrate carrier 18, which in the specific example also functions as substrate electrode 18 at the same time, so that a functional coating is produced and/or deposited on the substrate.

Enveloping gas 13 in the example presented here is argon, which is supplied to plasma jet source 5 at a gas flow rate of 5000 sccm to 100,000 sccm (standard cubic centimeters per minute), in particular 20,000 sccm to 70,000 sccm.

FIG. 1 also shows that coil 17 is electrically connected to a high-frequency generator 16 with which an electric power of 500 W to 50 kW, in particular 1 kW to 10 kW, at a high frequency of 0.5 MHz to 20 MHz is injected into coil 17, and is also input into the plasma 21 ignited and maintained in plasma generating space 27.

In a preferred embodiment, high-frequency generator 16 is provided with an essentially known electric component 28, with which the intensity of plasma jet 20 in its action on substrate 19 is variable periodically at a frequency of 1 Hz to 10 kHz, in particular 50 Hz to 1 kHz, between an adjustable upper intensity limit and an adjustable lower intensity limit. Plasma jet 20 is preferably also extinguished periodically for an adjustable period of time, i.e., a selectable pulse-pause ratio.

FIG. 1 also shows that a central gas 12 may be supplied through first sleeve 14 to the area between first sleeve 14 and inlet 10. This is, for example, an inert gas or an inert gas to which a gas that reacts with injector gas 11 is added.

A gaseous, microscale or nanoscale precursor material, a suspension of such a precursor material or a reactive gas in particular is supplied to plasma 20 through inlet 10 and/or an additional supply device located between first sleeve 14 and inlet 10, so that this reactive gas in modified form, in particular after undergoing a chemical reaction or a chemical activation, produces the desired functional coating on substrate 19 or is integrated into the functional coating there.

As an alternative, however, plasma 21 may also be used to merely produce a chemical modification in the surface of substrate 19, so that the desired functional coating is thereby produced on the surface of substrate 19.

If a precursor material is supplied to plasma 21, i.e., plasma jet 20, preferably at the same time a carrier gas for this precursor material, in particular nitrogen and/or a reactive gas for a chemical reaction with the precursor material, in particular oxygen, nitrogen, ammonia, a silane, acetylene, methane or hydrogen is also at the same time. Either inlet 10, the feeder device for supplying central gas 12 or the feeder device for supplying enveloping gas 13 is suitable for supplying these gases. As an alternative or in addition, another feeder device, e.g., an injector or a gas spray, may also be provided in chamber 40 to supply a reactive gas and/or a precursor material into plasma jet 20 which is already emerging from plasma jet source 5.

The precursor material used is preferably an organic compound, an organosilicon or organometallic compound, which may thus be supplied to plasma 21 and/or plasma jet 20 in a gaseous or liquid form, as microscale or nanoscale powder particles, as a liquid suspension, in particular having microscale or nanoscale particles suspended in it, or as a mixture of gaseous or liquid substances with solids. Through a suitable choice of the individual gases, i.e., the reactive gases supplied and/or central gas 12 and injector gas 11 as well as the choice of precursor materials, as explained in detail in German Published Patent Application No. 199 58 474, e.g., a metal silicide, a metal carbide, a silicon carbide, a metal oxide, a silicon oxide, a metal nitride, a silicon nitride, a metal boride, a metal sulfide, amorphous carbon, diamond-like carbon (DLC) or a mixture of these materials in the form of a layer or a sequence of layers may be produced on substrate 19. In addition, the method proposed here is also suitable for cleaning or carbonizing or nitriding the surface of substrate 19.

FIG. 1 also shows that substrate electrode 18 is coolable with cooling water 39 through a cooling water inlet 31, and substrate electrode 18 and thus also substrate 19 are movable in chamber 40 through an appropriate mount 32. Both mount 32 and cooling water supply 31 are electrically separated from substrate electrode 18, which receives the electric voltage, by insulation 34. Substrate 19 together with substrate electrode 18 is preferably situated on movable mount 32, in particular movable in all directions and/or rotatable in space.

In addition, substrate electrode 18 is electrically connected to a substrate generator 37 which provides an electric voltage to be injected into substrate electrode 18 and thereby also into substrate 19. To do so, generator lead 36 is provided between substrate generator 37 and substrate electrode 18.

Specifically, substrate electrode 18 together with substrate generator 37 receives a direct electric voltage or an alternating voltage having an amplitude between 10 V and 5 kV, in particular between 50 V and 300 V, and a frequency between 0 Hz and 50 MHz, in particular between 1 kHz and 100 kHz. This direct voltage or alternating voltage may also be provided continuously or intermittently with a positive or negative offset voltage.

The injected electric voltage is preferably an electric voltage that is variable over time, in particular a pulsed electric voltage having a pulse-pause ratio which may be selected on the basis of simple preliminary tests in the individual case, and an offset voltage which optionally also varies over time, e.g., with regard to polarity.

The variation in the electric voltage over time is preferably adjusted so that its envelope varies according to a unipolar or bipolar saw-tooth, triangular or sinusoidal curve. Additional parameters include the amplitude and polarity of the offset voltage, the edge steepness of the individual pulses of the electric voltage injected, the frequency (carrier frequency) of this voltage and its amplitude.

A particularly preferred embodiment of the method according to the present invention provides for the change in intensity of plasma jet 20 via high-frequency generator 16 and electric component 28 integrated into it, which may also be designed as a separate electric component and may then be connected between coil 17 and high-frequency generator 16, in particular the pulsing of plasma jet 20 to be correlated in time with the variation in or pulsation of the electric voltage injected into substrate electrode 18.

This time correlation is also preferably a pulsation (in phase opposition or with a time offset) of the intensity of plasma jet 20 with respect to the change in or pulsation of the electric voltage.

FIG. 1 also shows that a first pressure area 30 prevails in the interior of plasma jet source 5, where a pressure of 1 mbar to 2 bar prevails, in particular 100 mbar to 1 bar. Then a second pressure area 33 prevails in the interior of chamber 40.

In addition, conventional pumping equipment (not shown) is connected to chamber 40 to maintain the pressure difference between the first and second pressure areas 30, 33 and in particular to keep the pressure in chamber 40 less than 50 mbar, in particular between 1 mbar and 10 mbar. Therefore, a pressure gradient always exists between the interior of plasma jet source 5 and the interior of chamber 40, although gas is continuously supplied to plasma jet source 5 during operation, and plasma jet source 5 and chamber 40 are connected via outlet orifice 26.

The pressures are preferably selected so that the ratio of the pressure in first pressure area 30 to the pressure in second pressure area 33 is greater than 1.5, in particular greater than 3.

For example, a pressure difference of more than 100 mbar is maintained between plasma generating space 27 in the interior of plasma jet source 5 and the interior of chamber 40 by a pumping device (not shown) which is connected to chamber 40.

Suitable materials for substrate 19 include both electrically conducting materials and electrically insulating materials, the latter with a suitable choice of the variable voltage on the substrate electrode. In addition, the reduction in thermal load on substrate 19 due to the cooling device and in particular the pulsation of plasma jet 20 results in even thermally sensitive substrates such as polymers being usable.

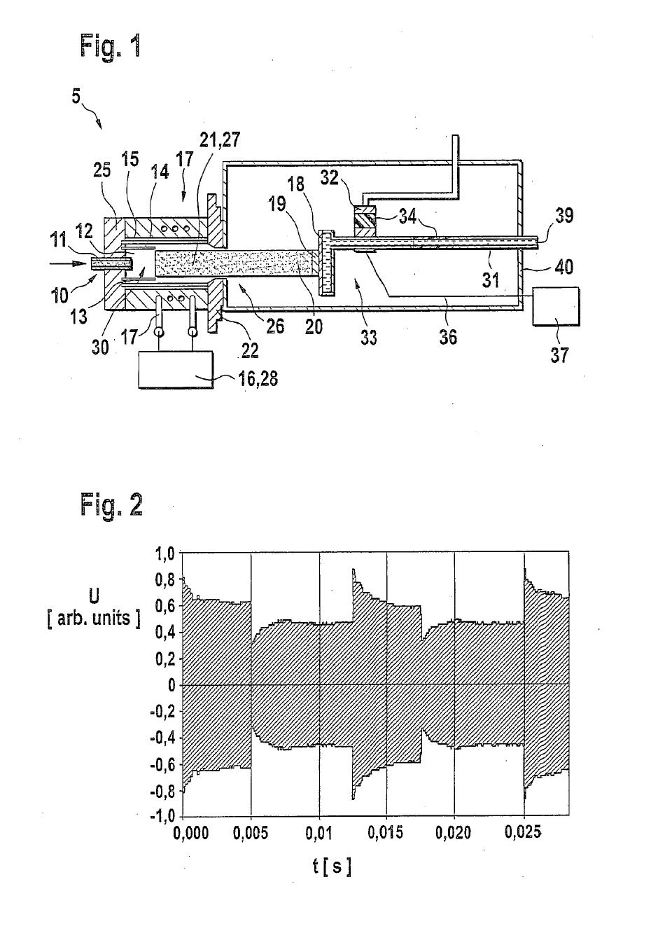

FIG. 2 illustrates how the intensity of plasma jet 20 is varied in accordance with the variation in the voltage supplied to coil 17, by varying the voltage supplied by high-frequency generator 16 cooperating with electric component 28 through a variation in the voltage supplied to the coil. In particular, in a further refinement of FIG. 2, the voltage on coil 17 may also be zero temporarily, so that plasma jet 20 is extinguished in this period of time.

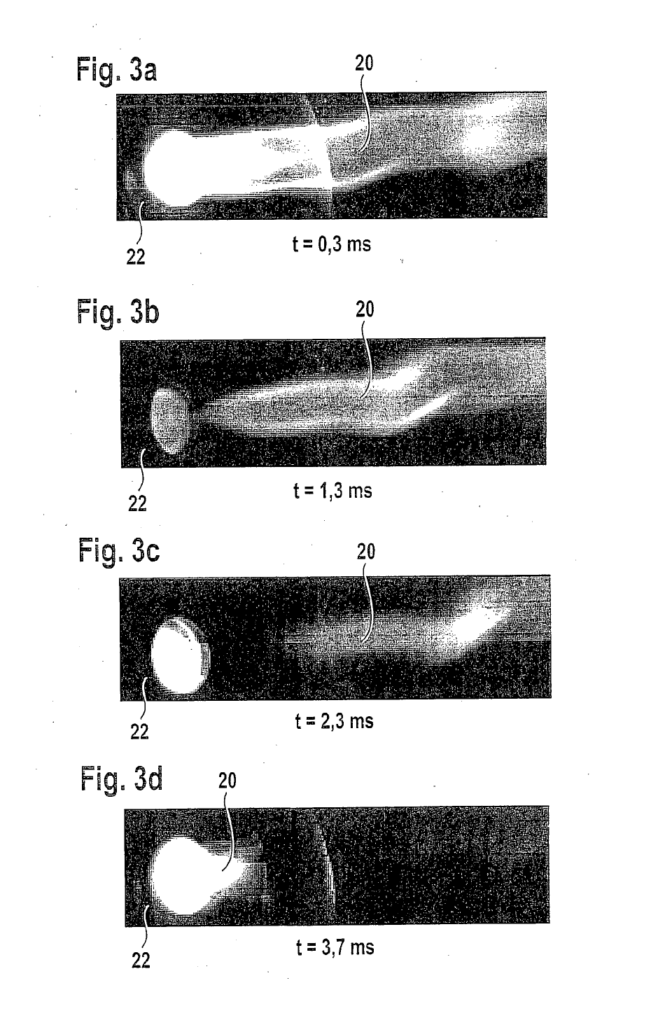

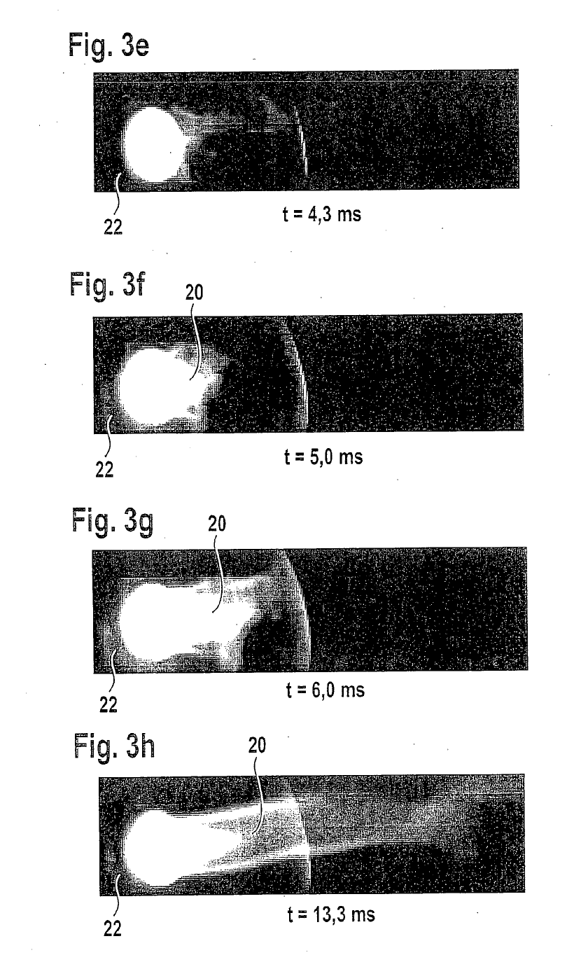

FIGS. 3a through 3h directly show plasma jet 20 emerging in chamber 40 from outlet orifice 26 through orifice restrictor 22. The typical distance between outlet orifice 26 and substrate 19 is 5 cm to 50 cm.

FIGS. 3a through 3h show how plasma jet 20 emerges from outlet orifice 26 at a high intensity initially according to FIG. 3a at time t=0, then this intensity drops significantly according to FIG. 3b, so that plasma jet 20 is extinguished completely shortly thereafter, then the plasma jet is reignited according to FIGS. 3c through 3e, and swings back briefly before then expanding continuously according to FIGS. 3f through 3h, so that after approx. 13.3 ms, the starting state according to FIG. 3a has almost been reached again. This pulsation of plasma jet 20 according to FIGS. 3a through 3h is induced by a change in the HF electric power injected into coil 17.

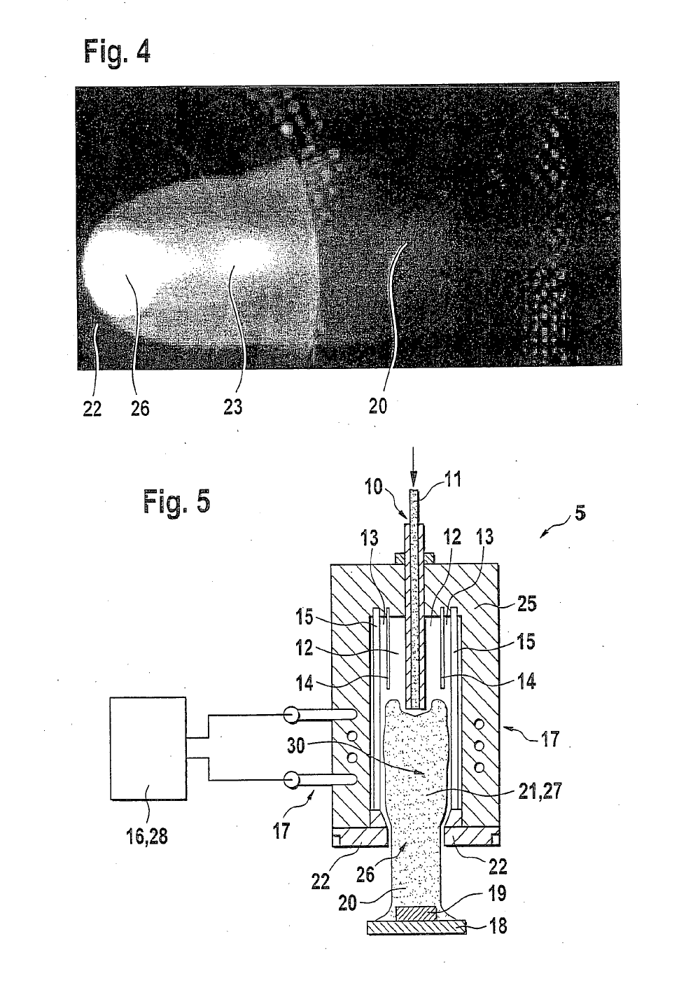

FIG. 4 illustrates how plasma jet 20 emerges from outlet orifice 26 at a high velocity due to a suitably high pressure difference between the interior of plasma jet source 5 and the interior of chamber 40, i.e., the pressure gradient with respect to chamber 40, as explained above, and impinges on substrate 19 with a correspondingly high velocity. In particular, compression nodes 23 (Mach nodes) are clearly discernible in FIG. 4, indicating that the velocity of the particles in plasma jet 20 is of the same order of magnitude as the velocity of sound. It may also be greater than the velocity of sound.

The high velocity of plasma jet 20, which is influenceable via the pressure difference, achieves the result that not only are deep cavities on the surface of substrate 19 acted upon by plasma 21, but also the diffusion interface between the surface of substrate 19 and plasma jet 20 is reduced in size, which facilitates diffusion of reactive plasma components onto the surface of substrate 19 and thus shortens and/or intensifies the required processing time of substrate 19 with plasma jet 20.

FIG. 5 illustrates a detail from FIG. 1, where plasma jet source 5 is shown again on an enlarged scale. In particular, the arrangement of inlet 10 and the embodiment of first sleeve 14 and second sleeve 15 are more clearly discernible.

What is claimed is:

1. A plasma system, comprising:
at least one inductively coupled high-frequency plasma jet source including a burner body delimiting a plasma generating space;
a chamber including an outlet orifice for a plasma jet, the chamber communicating with the at least one inductively coupled plasma jet source through the outlet orifice;
a substrate electrode capable of receiving an electric voltage; and
a substrate situated in the chamber and on the substrate electrode, the substrate being exposed to the plasma jet in the chamber.

2. The plasma system as recited in claim 1, further comprising:
a generator to which the substrate electrode is connected, the generator applying one of an electric direct voltage and an alternating voltage having an amplitude between 10 V and 5 kV and a frequency between 0 Hz and 50 MHz to the substrate electrode.

3. The plasma system as recited in claim 1, further comprising:
a generator to which the substrate electrode is connected, the generator applying to the substrate electrode one of an electric direct voltage and an alternating voltage having an amplitude between 50 V and 300 kV and a frequency between 1 kHz and 100 kHz.

4. The plasma system as recited in claim 1, wherein:
the burner body includes:
a coil surrounding the plasma generating space in some areas, and
at least one inlet for supplying at least one of a gas and a precursor material into the plasma generating space, and
a high-frequency generator is connected to the coil for igniting a plasma and for injecting an electric power into the plasma.

5. The plasma system as recited in claim 1, further comprising:
an arrangement for periodically varying an intensity of the plasma jet of the plasma jet source.

6. The plasma system as recited in claim 4, wherein:
the burner body is pot-shaped,
the coil one of surrounds the burner body in a vicinity of the outlet orifice and is integrated into the burner body in the vicinity of the outlet orifice,
an injector gas is supplied into the plasma generating space through the at least one inlet, and
the burner body includes at least one second inlet for supplying at least one of a central gas and an enveloping gas into the plasma generating space, the central gas reacting with the injector gas, and the enveloping gas separating the burner body from the plasma produced therein in at least some areas and concentrically surrounding the plasma in the plasma generating space.

7. The plasma system as recited in claim 4, wherein:
the burner body is pot-shaped,
the coil one of surrounds the burner body in a vicinity of the outlet orifice and is integrated into the burner body in the vicinity of the outlet orifice,
a precursor material for producing a functional coating on the substrate is supplied into the plasma generating space through the at least one inlet, and
the burner body includes at least one second inlet for supplying at least one of a central gas and an enveloping gas into the plasma generating space, the central gas reacting with the injector gas, and the enveloping gas separating the burner body from the plasma produced therein in at least some areas and concentrically surrounding the plasma into the plasma generating space.

8. The plasma system as recited in claim 1, further comprising:
a pumping device to which the chamber is connected in order to maintain at least one of:
a pressure difference of more than 100 mbar between the plasma generating space and an interior of the chamber in operation of the plasma system, and
a ratio of a pressure in the plasma generating space to a pressure in the interior of the chamber that is greater than 1.5.

9. The plasma system as recited in claim 1, further comprising:
a pumping device to which the chamber is connected in order to maintain at least one of:
a pressure difference of more than 100 mbar between the plasma generating space and an interior of the chamber in operation of the plasma system, and
a ratio of a pressure in the plasma generating space to a pressure in the interior of the chamber that is greater than 3.
